(19) United States
(12) Patent Application Publication
(10) Pub. No.: US 2014/0011299 A1
(43) Pub. Date: Jan. 9, 2014

(54) MANUFACTURING APPARATUS AND METHOD OF LIQUID CRYSTAL PANEL

(71) Applicant: Wen-da Cheng, Shenzhen (CN)

(72) Inventor: Wen-da Cheng, Shenzhen (CN)

(73) Assignee: Shenzhen China Star Optoelectronics Technology Co. Ltd., Shenzhen, Guangdong (CN)

(21) Appl. No.: 13/638,617

(22) PCT Filed: Jul. 13, 2012
(86) PCT No.: PCT/CN12/78606

§ 371 Date: Sep. 30, 2012

(30) Foreign Application Priority Data
Jul. 9, 2012 (CN) 201210235057.0
Jul. 13, 2012 (CN) PCT/CN12/78606

(51) Int. Cl. H01L 33/08; H01L 21/64

(52) U.S. Cl. 438/4; 445/61; 257/E33.053

(57) ABSTRACT

A manufacturing method of a liquid crystal panel, includes: cleaning a thin film transistor array substrate of the liquid crystal panel; performing an array detection on the cleaned thin film transistor array substrate; and processing the thin film transistor array substrate according to detecting result of the array detection. In the present disclosure, the TFT array substrate is cleaned after the array manufacturing process and is detected to determine whether the lines thereon are disconnected, and the disconnected lines are further repaired, which prevents the TFT array substrate with the disconnected lines from entering the cell device and reduces the scrap rate of the liquid crystal panel. Meanwhile, since the TFT array substrate is at first cleaned by the cleaning mechanism to remove the particles thereon and further is detected by the array detector, thus, the particles on the TFT array substrate is prevented from damaging the array detector.

### BACKGROUND

1. Technical Field

The present disclosure relates to manufacturing technologies of liquid crystal panels and, particularly, to a manufacturing apparatus and a manufacturing method of a liquid crystal panel.

2. Description of Related Art

Generally, manufacturing process of a thin film transistor (TFT) liquid crystal panel includes an array process and a cell process. A TFT array substrate and color filter (CF) are manufactured in the array process. In the cell process, alignment films are respectively formed on the TFT array substrate and the CF substrate, and the TFT array substrate and CF substrate are bonded together to allow liquid crystals to be injected to the space defined between the TFT array substrate and the CF substrate.

The TFT array substrate generally includes scan lines, data lines, a TFT array, and pixel electrodes. After being manufactured, the TFT substrate is detected to figure out whether there are defects of the scan lines and data lines before entering the cell process. Before coating the alignment film on the TFT array substrate, the TFT array substrate needs to be cleaned to remove particles or oil spots thereon.

However, during the process of removing the particles or oil spots, the scan lines or data lines on the TFT array substrate may be damaged. For example, in the process of cleaning the TFT array substrate, when the particles on the substrate are scratched off the substrate, the scan lines and date lines thereon are easily damaged, and the plating line formed on the TFT array substrate by the repairing machine may also be scratched off the substrate to cause the substrate to break down. Meanwhile, electronic energy level of the TFT array substrate may increase when the substrate is irradiated with ultraviolet light, which further results in the electric shock caused by static electricity before the alignment film is formed.

In the interval after the TFT array substrate is cleaned and before the alignment film is formed, the TFT array substrate is no longer detected. In this state, if the lines on the TFT array substrate are damaged when the substrate is cleaned in the array process and is further bonded to the CF substrate in the cell process, the liquid crystal panel may be provided with undesirable alignment or defects, which may further cause the liquid crystal panel to be wasted.

### SUMMARY

The present disclosure provides a manufacturing method of a liquid crystal panel, including:

cleaning a thin film transistor array substrate of the liquid crystal panel; performing an array detection on the cleaned thin film transistor array substrate; and

processing the thin film transistor array substrate according to detecting result of the array detection.

Preferably, the step of cleaning a thin film transistor array substrate of the liquid crystal panel includes:

washing the thin film transistor array substrate with water by a cleaning device;

cleaning the water-washed thin film transistor array substrate by the combination of ultrasound and cleaning agent; and

irradiating the thin film transistor array substrate with ultraviolet light.

Preferably, the step of processing the thin film transistor array substrate according to detecting result of the array detection includes:

if the detecting result of the array detection indicates that lines on the thin film transistor array substrate are disconnected, repairing the disconnected lines on the thin film transistor array substrate by a repairing device; and

transferring the repaired thin film transistor array substrate to allow a cell process to be implemented.

Preferably, the step of processing the thin film transistor array substrate according to detecting result of the array detection includes:

if the detecting result of the array detection indicates that no lines on the thin film transistor array substrate are disconnected, transferring the thin film array substrate to allow the cell process to be implemented.

Preferably, the step of processing the thin film transistor array substrate according to detecting result of the array detection includes:

forming an alignment film on the thin film transistor array substrate in a cell device, bonding the thin film transistor array substrate and a color filter substrate, and injecting liquid crystals into space defined between the thin film transistor array substrate and the color filter substrate.

Preferably, the step of cleaning the water-washed thin film transistor array substrate by the combination of ultrasound and cleaning agent includes:

sprinkling water towards the thin film transistor array substrate via a water sprinkling member and cleaning the thin film transistor array substrate via a brush engageable with the water sprinkling member.

The present disclosure further provides a manufacturing apparatus of a liquid crystal panel, including:

a cleaning mechanism, configured for cleaning a thin film transistor array substrate of the liquid crystal panel;

an array detector, configured for performing an array detection on the cleaned thin film transistor array substrate;

a repairing device, configured for repairing disconnected lines on the thin film transistor array substrate; and

a cell device, configured for forming an alignment film on the thin film transistor array substrate, bonding the thin film transistor array substrate and a color filter substrate, and injecting liquid crystals into space defined between the thin film transistor array substrate and the color filter substrate.

Preferably, the cleaning mechanism includes:

a cleaning device, configured for washing the thin film transistor array substrate with water to remove particles of relatively larger sizes;

an ultrasonic device, configured for combining with cleaning agent to clean the thin film transistor array substrate to remove particles of relatively smaller sizes; and

an ultraviolet irradiating device, configured for irradiating the thin film transistor with ultraviolet light emitted therefrom to remove organic compound on the thin film transistor array substrate.

Preferably, the cleaning device includes a water sprinkling member for sprinkling water towards the thin film transistor array substrate and a brush engageable with the water sprinkling member for cleaning the thin film transistor array substrate.

Preferably, the repairing device is configured for repairing the disconnected lines on the thin film transistor array substrate when the detecting result of the array detection indicates that the lines on the thin film transistor array substrate are disconnected.

The present disclosure further provides another manufacturing apparatus of a liquid crystal panel, including:

a cleaning mechanism, configured for cleaning a thin film transistor array substrate of the manufacturing apparatus;

an array detector, configured for performing an array detection on the thin film transistor array substrate; and

a repairing device, configured for repairing disconnected lines on the thin film transistor array substrate.

Preferably, the cleaning mechanism includes:

a cleaning device, configured for washing the thin film transistor array substrate with water to remove particles of relatively larger sizes;

an ultrasonic device, configured for combining with cleaning agent to clean the thin film transistor array substrate to remove particles of relatively smaller sizes; and

an ultraviolet irradiating device, configured for irradiating the thin film transistor with ultraviolet light emitted therefrom to remove organic compound on the thin film transistor array substrate.

Preferably, the cleaning device includes a water sprinkling member for sprinkling water towards the thin film transistor array substrate and a brush engageable with the water sprinkling member for cleaning the thin film transistor array substrate.

Preferably, the repairing device is configured for repairing the disconnected lines on the thin film transistor array substrate when the detecting result of the array detection indicates that the lines on the thin film transistor array substrate are disconnected.

In the manufacturing apparatus and manufacturing method of the present disclosure, the TFT array substrate is cleaned when the array manufacturing process is finished and is detected to determine whether the lines thereon are disconnected, and the disconnected lines are further repaired. This prevents the TFT array substrate with the disconnected lines disconnected in the cleaning process thereof from entering the cell device and reduces the scrap rate of the liquid crystal panel. Meanwhile, since the TFT array substrate is at first cleaned by the cleaning mechanism to remove the particles thereon and further is detected by the array detector, thus, the particles on the TFT array substrate are prevented from damaging the array detector.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a schematic view illustrating a manufacturing apparatus of a liquid crystal panel in accordance with an embodiment of the present disclosure;

FIG. 2 is a schematic view illustrating a cleaning mechanism of the manufacturing apparatus of FIG. 1;

FIG. 3 is a flow chart of a manufacturing method of the liquid crystal panel in accordance with an embodiment of the present disclosure.

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

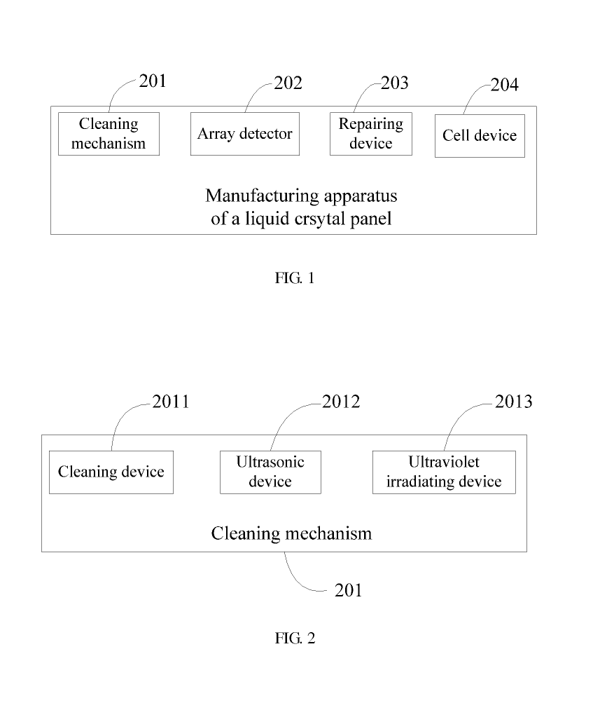

Referring to FIG. 1, the present disclosure provides a manufacturing apparatus of a liquid crystal panel. In one embodiment, the manufacturing apparatus includes a cleaning mechanism 201, an array detector 202, a repairing device 203, and a celling device 204.

The cleaning mechanism 201 is configured for cleaning a thin film transistor (TFT) array substrate of the liquid crystal panel having a TFT array, data lines, scan lines, and pixel electrodes.

The array detector 202 is configured for detecting the cleaned TFT array substrate to determine whether the data lines or scan lines on the substrate are broken or not.

The repairing device 203 is configured for repairing the broken data lines or scan lines on the TFT array substrate.

The celling device 204 is configured for forming an alignment film on the TFT array substrate, bonding a CF substrate to the TFT array substrate to allow liquid crystals to be injected into the space defined therebetween.

In the embodiment, after the array process of the TFT array substrate is finished, the cleaning mechanism 201 cleans the TFT array substrate and the array detector 202 performs an array detection on the TFT array substrate.

Referring to FIG. 2, the cleaning mechanism 201 includes a cleaning device 2011, an ultrasonic device 2012, and an ultraviolet irradiating device 2013.

The cleaning device 2011 is used for washing the TFT array substrate with water to remove particles of relatively larger sizes. The ultrasonic device 2012 is used for radiating ultrasound wave which can be combined with cleaning agent to clean the water-washed TFT array substrate, and thus removing particles of relatively smaller sizes. The ultraviolet irradiating device 2013 is used for radiating ultraviolet light to the TFT array substrate and thus removing organic compound thereon such as oil spots.

Specifically, the cleaning device 2011 includes a water sprinkling member for sprinkling water towards the TFT array substrate and a brush for rollably cleaning the TFT array substrate while the water sprinkling device is sprinkling water.

As mentioned above, cleaning the TFT array substrate may disconnect the lines on the substrate or bring about other defects of the substrate, for example, when the substrate is cleaned by the cleaning device 2011 and the ultrasonic device 2012 to remove the particles thereon, the lines on the substrate may be disconnected; when the TFT array substrate is irradiated with ultraviolet light from the ultraviolet irradiating device 2013, electronic energy level of the TFT array substrate may increase when the substrate is irradiated with ultraviolet light, which further results in the electric shock caused by static electricity before the alignment film is formed and thus the waste of the liquid crystal panel.

Therefore, after the cleaning mechanism 201 cleans the TFT array substrate, the array detector 202 performs the array detection on the TFT array substrate to determine whether the lines thereon are disconnected and thus prevents the liquid crystal panel from being wasted.

The repairing device 203 is used for repairing the disconnected lines on the TFT array substrate detected by the array detector 202.

Specifically, the array detector 202 performs the array detection on the cleaned TFT array substrate. Since the TFT array substrate is configured with the TFT array, data lines, scan lines, and pixel electrodes, the array detection in the embodiment is referred to a detection of the data lines and scan lines on the substrate which is capable of determining whether the lines are disconnected.

If the detecting result from the array detector 202 indicates that the lines on the TFT array substrate are disconnected, the repairing device 203 repairs the disconnected lines and transfers the repaired TFT array substrate to the cell device 204. If the detecting result from the array detector 202 indicates that no lines on the TFT array substrate are disconnected, the substrate is transferred to the cell device 204.

The cell device 204 is configured for forming two alignment films on the TFT array substrate, the CF substrate respectively, coating sealant on the TFT array substrate or the CF substrate, dropping the liquid crystal on the CF substrate or the TFT array substrate correspondingly, bonding the TFT array substrate to the CF substrate, and carrying out optical alignment process on the two bonded substrates.

In the present disclosure, the TFT array substrate with the disconnected lines caused by the cleaning mechanism 201 in the cleaning process of cleaning the substrate is prevented from entering the cell device 204, which reduces the waste of the liquid crystal panel. Meanwhile, since the TFT array substrate is detected after being cleaned by the cleaning mechanism 201, the particles on the TFT array substrate can be removed to avoid damaging the array detector 202.

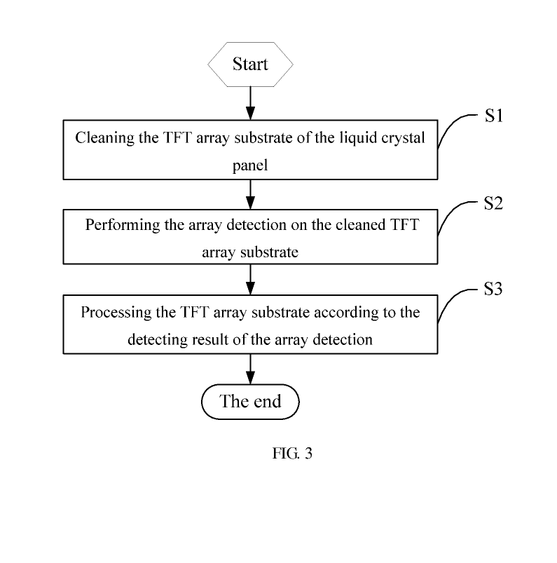

Referring to FIG. 3, the present disclosure also provides a manufacturing method of the liquid crystal panel. The manufacturing method includes the following steps:

Step S1, cleaning the TFT array substrate of the liquid crystal panel. After the array process, data lines, scan lines, and pixel electrodes are formed on the TFT array substrate and the cleaning mechanism 201 begins to clean the TFT array substrate.

Specifically, firstly, the cleaning device 2011 cleans the TFT array substrate with water to remove particles of relatively larger sizes; secondly, the ultrasonic device 2012 radiates ultrasound which can be combined with cleaning agent to clean the water-washed TFT array substrate, thus removes the particles of relatively smaller sizes; finally, the ultraviolet irradiating device 2013 irradiates the TFT array substrate with ultraviolet light emitted therefrom to remove organic compound such as oil spots on the substrate.

The cleaning device 2011 includes a water sprinkling member for sprinkling water towards the array substrate and a brush for rollably cleaning the TFT array substrate while the water sprinkling member is sprinkling water.

Step S2, performing the array detection on the cleaned TFT array substrate. Since the TFT array substrate is configured with the TFT array, the data lines, the scan lines, and the pixel electrodes, the array detection is referred to a detection of the data lines and the scan lines on the substrate which is capable of determining whether the lines on the substrate are disconnected.

As mentioned above, cleaning the TFT array substrate may disconnect the lines on the substrate or bring about other defects of the substrate, for example, when the substrate is cleaned by the cleaning device 2011 and the ultrasonic device 2012 to remove the particles thereon, the lines on the substrate may be disconnected; when the TFT array substrate is irradiated with ultraviolet light from the ultraviolet irradiating device 2013, electronic energy level of the TFT array substrate may increase when the substrate is irradiated with ultraviolet light, which further results in the electric shock caused by static electricity before the alignment film is formed and thus the waste of the liquid crystal panel.

Therefore, after the cleaning mechanism 201 cleans the TFT array substrate, the array detector 202 performs the array detection on the TFT array substrate to determine whether the lines on the substrate are disconnected and thus prevent the liquid crystal panel from being wasted.

Step S3, processing the TFT array substrate according to the detecting result.

Specifically, the array detector 202 performs the array detection on the cleaned TFT array substrate. If the detecting result from the array detector 202 indicates that the lines on the TFT array substrate are disconnected, the repairing device 203 repairs the disconnected lines and transfers the repaired TFT array substrate to the cell device 204 to allow for the implementation of the cell process. If the detecting result from the array detector 202 indicates that no lines on the TFT array substrate are disconnected, the substrate is transferred to the cell device 204 to allow for the implementation of the cell process.

The cell process includes forming alignment films on the TFT array substrate and the CF substrate respectively, coating sealant on the TFT array substrate or on the CF substrate, dropping the liquid crystal on the CF substrate or the TFT array substrate correspondingly, bonding the TFT array substrate to the CF substrate, and carrying out optical alignment process on the two bonded substrates.

In the present disclosure, the TFT array substrate with the disconnected lines caused by the cleaning mechanism 201 in the cleaning process of cleaning the substrate is prevented from entering the cell device 204, which reduces the waste of the liquid crystal panel. Meanwhile, since the TFT array substrate is detected after being cleaned by the cleaning mechanism 201, the particles on the TFT array substrate can be removed to avoid damaging the array detector 202.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A manufacturing method of a liquid crystal panel, comprising:
cleaning a thin film transistor array substrate of the liquid crystal panel;
performing an array detection on the cleaned thin film transistor array substrate; and
processing the thin film transistor array substrate according to detecting result of the array detection.

2. The manufacturing method as claimed in claim 1, wherein the step of cleaning a thin film transistor array substrate of the liquid crystal panel comprises:
washing the thin film transistor array substrate with water by a cleaning device;
cleaning the water-washed thin film transistor array substrate by the combination of ultrasound and cleaning agent; and
irradiating the thin film transistor array substrate with ultraviolet light.

3. The manufacturing method as claimed in claim 1, wherein the step of processing the thin film transistor array substrate according to detecting result of the array detection comprises:
if the detecting result of the array detection indicates that lines on the thin film transistor array substrate are disconnected, repairing the disconnected lines on the thin film transistor array substrate by a repairing device; and
transferring the repaired thin film transistor array substrate to allow a cell process to be implemented.

4. The manufacturing method as claimed in claim 3, wherein the step of processing the thin film transistor array substrate according to detecting result of the array detection comprises:
if the detecting result of the array detection indicates that no lines on the thin film transistor array substrate are disconnected, transferring the thin film array substrate to allow the cell process to be implemented.

5. The manufacturing method as claimed in claim 1, wherein the step of processing the thin film transistor array substrate according to detecting result of the array detection comprises:
forming an alignment film on the thin film transistor array substrate by a cell device, bonding the thin film transistor array substrate and a color filter substrate, and injecting liquid crystals into space defined between the thin film transistor array substrate and the color filter substrate.

6. The manufacturing method as claimed in claim 2, wherein the step of cleaning the water-washed thin film transistor array substrate by the combination of ultrasound and cleaning agent comprises:
sprinkling water towards the thin film transistor array substrate via a water sprinkling member and cleaning the thin film transistor array substrate via a brush engaging with the water sprinkling member.

7. A manufacturing apparatus of a liquid crystal panel, comprising:
a cleaning mechanism, configured for cleaning a thin film transistor array substrate of the liquid crystal panel;
an array detector, configured for performing an array detection on the cleaned thin film transistor array substrate;
a repairing device, configured for repairing disconnected lines on the thin film transistor array substrate; and
a cell device, configured for forming an alignment film on the thin film transistor array substrate, bonding the thin film transistor array substrate and a color filter substrate, and injecting liquid crystals into space defined between the thin film transistor array substrate and the color filter substrate.

8. The manufacturing apparatus as claimed in claim 7, wherein the cleaning mechanism comprises:
a cleaning device, configured for washing the thin film transistor array substrate with water to remove particles of relatively larger sizes;
an ultrasonic device, configured for combining with cleaning agent to clean the thin film transistor array substrate to remove particles of relatively smaller sizes; and
an ultraviolet irradiating device, configured for irradiating the thin film transistor with ultraviolet light emitted therefrom to remove organic compound on the thin film transistor array substrate.

9. The manufacturing apparatus as claimed in claim 8, wherein the cleaning device comprises a water sprinkling member for sprinkling water towards the thin film transistor array substrate and a brush engageable with the water sprinkling member for cleaning the thin film transistor array substrate.

10. The manufacturing apparatus as claimed in claim 7, wherein the repairing device is configured for repairing the disconnected lines on the thin film transistor array substrate when the detecting result of the array detection indicates that the lines on the thin film transistor array substrate are disconnected.

11. A manufacturing apparatus of a liquid crystal panel, comprising:
a cleaning mechanism, configured for cleaning a thin film transistor array substrate of the manufacturing apparatus;
an array detector, configured for performing an array detection on the thin film transistor array substrate; and
a repairing device, configured for repairing disconnected lines on the thin film transistor array substrate.

12. The manufacturing apparatus as claimed in claim 11, wherein the cleaning mechanism comprises:
a cleaning device, configured for washing the thin film transistor array substrate with water to remove particles of relatively larger sizes;
an ultrasonic device, configured for combining with cleaning agent to clean the thin film transistor array substrate to remove particles of relatively smaller sizes; and
an ultraviolet irradiating device, configured for irradiating the thin film transistor with ultraviolet light emitted therefrom to remove organic compound on the thin film transistor array substrate.

13. The manufacturing apparatus as claimed in claim 12, wherein the cleaning device comprises a water sprinkling member for sprinkling water towards the thin film transistor array substrate and a brush engageable with the water sprinkling member for cleaning the thin film transistor array substrate.

14. The manufacturing apparatus as claimed in claim 11, wherein the repairing device is configured for repairing the disconnected lines on the thin film transistor array substrate when the detecting result of the array detection indicates that the lines on the thin film transistor array substrate are disconnected.
